(19) United States
(12) Patent Application Publication
(10) Pub. No.: US 2022/0267660 A1
(43) Pub. Date: Aug. 25, 2022

(54) HEAT DISSIPATION SHEET, METHOD FOR MANUFACTURING SAME, AND ELECTRONIC DEVICE INCLUDING SAME

(71) Applicant: AMOGREENTECH CO., LTD., Gimpo-si (KR)

(72) Inventor: Jin Hyoung LEE, Gimpo-si (KR)

(21) Appl. No.: 17/662,066

(22) Filed: May 4, 2022

Related U.S. Application Data
(63) Continuation of application No. PCT/KR2020/015515, filed on Nov. 6, 2020.

(30) Foreign Application Priority Data
Nov. 6, 2019 (KR) 10-2019-0141073

(51) Int. Cl. C09K 5/14; H05K 7/20; C08J 5/18; C08J 3/24; C08K 9/06; C08L 15/00

(52) U.S. Cl. CPC C09K 5/14; H05K 7/2039; C08J 5/18; C08J 3/24; C08K 9/06; C08L 2203/20; C08J 2315/00; C08K 2201/001; C08K 2201/005; C08L 2312/00; C08L 15/00

(57) ABSTRACT

Disclosed is a heat dissipation sheet. The heat dissipation sheet according to an embodiment of the present invention is implemented to include a matrix formed of a main resin including a rubber-based resin, and a heat dissipation filler dispersed in the matrix and having a modified surface. Accordingly, as the compatibility between dissimilar materials forming the heat dissipation sheet increases, the heat dissipation performance is more improved. In addition, although it is designed to have excellent heat dissipation performance, the cracking, shrinkage, and pore generation of the sheet can be minimized or prevented, so that the sheet can have excellent flexibility.

### CROSS-REFERENCE TO RELATED APPLICATION

This application is a continuation of pending PCT International Application No. PCT/KR2020/015515, filed on Nov. 6, 2020, which claims priority to Korean Patent Application No. 10-2019-0141073 filed on Nov. 6, 2019, the entire contents of which are hereby incorporated by references in its entirety.

### TECHNICAL FIELD

The present invention relates to a heat dissipation sheet, a method for manufacturing the same and an electronic device including the same.

### BACKGROUND ART

Recently, as electronic devices become highly integrated with light, thin, short and multifunctional, heat generation increases, and countermeasures are required. In particular, dissipating the heat generated in electronic devices is very important because it is closely related to the reliability and longevity of the device.

In the past, various heat dissipation devices such as heat dissipation fans, heat dissipation fins, and heat pipes have been developed, and recently, various heat dissipation composites such as heat dissipation pads, heat dissipation sheets, and heat dissipation paints added with fillers that express heat dissipation performance in polymer materials have also been developed to assist or replace the heat dissipation devices.

However, materials known to have high heat dissipation performance generally have low resistance and high dielectric constant, so that there is a problem in that the performance of other parts in electronic devices to which the heat dissipation composite is applied is deteriorated, or an intended function of the parts is lost.

In addition, when a filler expressing heat dissipation performance is mixed with a polymer material, there is a limit to increasing the filler content as the filler is non-uniformly dispersed in the polymer material due to a decrease in compatibility between these dissimilar materials, so there is a problem that it is difficult to express sufficient heat dissipation to a desired level.

### DISCLOSURE

### Technical Problem

The present invention has been devised in view of the above matters, and an object of the present invention is to provide a heat dissipation sheet having improved heat dissipation performance by improving compatibility between dissimilar materials, and a method for manufacturing the same.

In addition, another object of the present invention is to provide a heat dissipation sheet capable of reducing or preventing the occurrence of cracking, shrinkage, and pores of the sheet even though it is designed to have excellent heat dissipation performance, and having excellent flexibility, and a method for manufacturing the same.

Furthermore, another object of the present invention is to provide various industrial articles such as electronic devices, in which the functional degradation of parts due to heat is minimized by rapidly transferring heat to prevent functional degradation or deterioration of parts around a heat source.

### Technical Solution

In order to solve the above problems, the present invention provides a heat dissipation sheet includes a matrix including a crosslinked rubber-based resin, and a heat dissipation filler which is dispersed in the matrix and of which surface is modified with a silane compound.

According to an embodiment of the present invention, the heat dissipation filler may be provided in 90% by weight or more based on a total weight of the matrix and the heat dissipation filler.

In addition, the heat dissipation filler may include the heat dissipation filler having a resistance of 1×10¹⁴Ω or more.

In addition, the heat dissipation filler may include the heat dissipation filler having a dielectric constant of 10 or less at a frequency of 28 GHz.

In addition, the heat dissipation filler may have a plate shape.

In addition, the heat dissipation filler may have an average particle diameter of 20 to 40 μm.

In addition, the heat dissipation sheet may have a density of 1.8 g/m³ or more.

In addition, the rubber-based resin may include one or more selected from the group consisting of isoprene rubber (IR), butadiene rubber (BR), styrene-butadiene rubber (SBR), ethylene propylene diene monomer (EPDM) rubber, acrylic rubber, nitrile-butadiene rubber (NBR) and silicone rubber.

In addition, the rubber-based resin may be crosslinked through a crosslinking agent including an isocyanate-based compound.

In addition, the silane compound may include amino silane compound.

In addition, the amino silane compound may include one or more selected from the group consisting of 3-aminopropyltriethoxysilane, 3-aminopropyltrimethoxysilane and 3-aminopropylmethyldimethoxysilane.

In addition, the matrix may include a crosslinked product in which styrene-butadiene rubber (SBR) is crosslinked with a crosslinking agent of an isocyanate-based compound, and the silane compound may be an amino silane compound.

In addition, the amino silane compound may be included in an amount of 1.0 to 4.0 parts by weight based on 100 parts by weight of the heat dissipation filler.

In addition, the heat dissipation filler may have a plate shape, and may include a first heat dissipation filler having a particle diameter of 3 to 7 μm and a second heat dissipation filler having a particle diameter of 25 to 40 μm in a weight ratio of 1:7.5 to 9.5.

In addition, the heat dissipation filler may have a spherical shape, and may include a third heat dissipation filler having a particle diameter of 0.2 to 0.8 μm, a fourth heat dissipation filler having a particle diameter of 3 to 7 μm, and a fifth heat dissipation filler having a particle diameter of 25 to 50 μm in a weight ratio of 1:1.7 to 3.0:9.0 to 11.0.

In addition, the present invention provides a method for manufacturing a heat dissipation sheet including the steps of (1) preparing a heat dissipation filler of which surface is modified with a silane compound, (2) preparing a preliminary sheet by mixing the heat dissipation filler with a rubber-based resin and a crosslinking agent, and (3) crosslinking the rubber-based resin while pressing the prepared preliminary sheet.

According to an embodiment of the present invention, the step (3) may be performed by a plate press method or a calendar method.

In addition, the step (3) may include the steps of crosslinking the preliminary sheet while applying heat and pressure at a temperature of 100 to 180° C. and cooling the crosslinked preliminary sheet to a temperature of 18 to 60° C. while applying pressure.

In addition, the present invention provides an electronic device including the heat dissipation sheet of the present invention.

### Advantageous Effect

According to the present invention, the heat dissipation sheet has more improved heat dissipation performance due to an increase in compatibility between dissimilar materials forming the heat dissipation sheet. In addition, although it is designed to have excellent heat dissipation performance, the cracking, shrinkage, porosity of the sheet and the lifting and separation between the matrix and the heat dissipation filler in the sheet are minimized or prevented, so that excellent flexibility can be achieved. Furthermore, a dielectric constant may be designed to be low. In addition, the heat dissipation sheet according to an embodiment of the present invention, which has low dielectric characteristics and excellent heat dissipation characteristics, can prevent deterioration or loss of function of an electronic part such as an antenna of which performance can be degraded or lost due to the dielectric constant, even when disposed adjacent to such electronic part, so the heat dissipation sheet can be widely applied to various electronic devices in overall industry.

### DESCRIPTION OF DRAWINGS

FIGS. 1 and 2 are SEM photographs of the surface of a heat dissipation sheet manufactured by different methods according to an embodiment of the present invention.

FIGS. 3 to 5 are photographs of experimental results confirming whether a matrix is separated after peeling off a protective film for the heat dissipation sheets according to Examples 13, 19 and 20, respectively.

FIGS. 6 to 9 are graphs of adhesive strength according to a peeling length of a protective film in Examples 13, 23, 19 and 20, respectively.

### MODE FOR INVENTION

Hereinafter, embodiments of the present invention will be described in detail so that those of ordinary skill in the art can easily implement them. The present invention may be embodied in many different forms and is not limited to the embodiments described herein.

The heat dissipation sheet according to an embodiment of the present invention includes a matrix and a heat dissipation filler which is dispersed in the matrix and of which surface is modified with a silane compound, and the matrix includes a crosslinked rubber-based resin.

The heat dissipation filler is a component that imparts thermal conductivity to the heat dissipation sheet. The heat dissipation filler is the one used in the heat dissipation sheet and has thermal conductivity, and known heat dissipation fillers of metal, alloy, ceramic, and carbon may be used without limitation. In addition, according to the purpose, the heat dissipation filler can be selected by appropriately considering dielectric properties in addition to thermal conductivity. For example, if it is desired to realize a heat dissipation sheet that can achieve both low dielectric constant and high heat dissipation characteristics at the same time, heat dissipation fillers such as alumina, yttria, zirconia, aluminum nitride, boron nitride, silicon nitride, silicon carbide and single crystal silicon may be selected and implemented. More preferably, in order to express the low dielectric characteristics of the heat dissipation sheet itself after being implemented as the heat dissipation sheet, the heat dissipation filler may include a dielectric constant of 10 or less at a frequency of 28 GHz. If the heat dissipation filter having the dielectric constant exceeding 10 is used at the corresponding frequency, it may be difficult to achieve a desired level of dielectric constant of the heat dissipation sheet. In particular, if the heat dissipation filler in the heat dissipation sheet is provided with a high content, it may be more difficult to achieve a desired level of dielectric constant of the heat dissipation sheet. In addition, the heat dissipation filler may include a resistance of 1×10¹⁴Ω or more, which is advantageous to achieve a low dielectric constant of the heat dissipation sheet at a desired level.

In terms of dielectric constant and resistance as described above, the heat dissipation filler may include, for example, one or more selected from the group consisting of alumina, aluminum nitride, boron nitride, silicon nitride and silicon carbide, more preferably one or more selected from the group consisting of alumina, boron nitride, silicon nitride and silicon carbide, but is not limited thereto.

In addition, the heat dissipation filler is not limited in shape. For example, the heat dissipation filler may have a spherical or plate-like granular shape, and it may be advantageous for the heat dissipation filler to have a plate shape in terms of improving thermal conductivity in the horizontal direction. Heat in an electronic device may be caused by all parts in an electronic device, but there may be a hotspot area where the heat is significantly greater in a particular part. In this case, the high thermal conductivity in the horizontal direction centered on the hotspot area has an advantage in that the heat concentrated in the hotspot can be quickly dispersed to the periphery to prevent the heat from being concentrated.

In addition, the heat dissipation filler may have an average particle diameter of 1 to 200 μm. However, according to an embodiment of the present invention, the heat dissipation filler may have an average particle diameter of 2 to 50 μm, more preferably 2 to 40 μm, even more preferably 20 to 40 μm. For example, the average particle diameter may be 20 to 33 μm. The heat dissipation filler of such a particle size may be provided in a high content of 90% by weight or more in the heat dissipation sheet. When the particle size of the heat dissipation filler is adjusted to an appropriate level, it becomes easy to provide the heat dissipation filler with a high content in the heat dissipation sheet, the sheet formability can be improved, and a surface quality can be improved by preventing the heat dissipation filler from sticking to the surface after sheet formation. If the average particle diameter of the heat dissipation filler exceeds 200 μm, it is difficult to provide the heat dissipation filler with a high content in the matrix implemented with a rubber-based resin, and even if it is manufactured with the heat dissipation filler of a high content, it is not very easy to form a sheet, and the surface quality may be deteriorated. However, the heat dissipation filler may have the average particle diameter of 1 μm or more, preferably 2 μm or more, and more preferably 20 μm or more. Through this, dispersibility and content in the matrix can be further increased, which has the advantage of further improving thermal conductivity. On the other hand, in the present invention, the particle diameter of the heat dissipation filler refers to the diameter when the shape is spherical, the particle diameter refers to the longest distance among the linear distances between two different points on the surface when the shape is a polyhedron or amorphous shape rather than a plate shape, or the particle diameter refers to the longest distance among the straight-line distances between two different points of the upper or lower edge when the shape is plate shape.

In addition, the heat dissipation filler is provided with an improved content in the heat dissipation sheet, and in order to have improved heat dissipation characteristics, flexibility, surface quality and mechanical characteristics, the heat dissipation filler can be designed in several particle size groups having different particle sizes. Specifically, when the heat dissipation filler is a plate shape, it is preferable to include a first heat dissipation filler having the particle diameter of 3 to 7 μm and a second heat dissipation filler having the particle size of 25 to 40 μm in a weight ratio of 1:7.5 to 9.5. Specifically, the first heat dissipation filler may have the particle diameter of 5 μm, and the second heat dissipation filler may have the particle diameter of 30 μm. In addition, when the heat dissipation filler is spherical, the particle size of the heat dissipation filler may be controlled to include a third heat dissipation filler having the particle diameter of 0.2 to 0.8 μm, a fourth heat dissipation filler having the particle diameter of 3 to 7 μm, and a fifth heat dissipation filler having the particle diameter of 25 to 50 μm. For example, the third heat dissipation filler may have the particle diameter of 0.5 μm, the fourth heat dissipation filler may have the particle diameter of 4 μm, and the fifth heat dissipation filler may have the particle diameter of 30 μm. More preferably, the third heat dissipation filler, the fourth heat dissipation filler, and the fifth heat dissipation filler may be included in a weight ratio of 1:1.7 to 3.0:9.0 to 11.0. When the particle size is adjusted in this way according to the shape of the heat dissipation filler, it is possible to achieve a more elevated effect of the above-mentioned desired physical properties. If any one of the first heat dissipation filler and the second heat dissipation filler, or any one or more of the third heat dissipation filler to the fifth heat dissipation filler is designed to deviate from the above-mentioned particle diameter range, or if their contents are included in the heat dissipation filler so as to be outside the above-mentioned range, it may be difficult to achieve the desired effect.

On the other hand, the heat dissipation filler may have a problem with compatibility with the polymer resin forming the matrix, and if the compatibility is not good, the thermal conductivity at the interface between the polymer resin and the heat dissipation filler may decrease, so that micro-lift phenomenon at the interface can be occurred, which may further reduce heat dissipation performance. In addition, since it may cause cracks or separation of the matrix in the corresponding portion, the durability of the heat dissipation sheet may also be deteriorated. Furthermore, the dispersibility of the heat dissipation filler in the polymer resin may be significantly reduced. If the dispersibility of the heat dissipation filler is not good, it may be very difficult to design the heat dissipation filler with a high content in the heat dissipation sheet, and thus it may be difficult to implement high heat dissipation characteristics.

The present invention is provided with a heat dissipation filler with a modified surface in order to solve this problem. The surface-modified heat dissipation filler can minimize or prevent the above problems by increasing the compatibility with a matrix forming resin, particularly a crosslinked rubber-based resin, more specifically, a matrix in which styrene-butadiene rubber resin is crosslinked by an isocyanate-based crosslinking agent.

In addition, with respect to the modification, any known modification capable of increasing the compatibility between the heat dissipation filler and the matrix forming resin may be used without limitation. However, preferably, the modification may be the modification with a silane compound. The silane compound may be, for example, an amino silane compound, an epoxy silane compound, a vinyl silane compound, and a silane compound containing a metal element. Through the use of such a silane compound, there is an advantage in which the interface characteristics between the matrix and the heat dissipation filler is improved, which has the advantage of implementing heat dissipation characteristics. More preferably, the silane compound may be an amino silane compound. When a different type of silane compound is used, it is difficult to prevent damage to the matrix portion in the heat dissipation sheet, and there is a risk that the heat dissipation characteristics may also be deteriorated due to the damage. In addition, in the case of epoxy silane, the heat dissipation characteristics may be rather deteriorated. In particular, when the heat dissipation filler is provided in a high content such that it is 90% by weight or more in the matrix, and the shape of the heat dissipation filler is plate or the surface of the heat dissipation filler is smooth due to low roughness, or even when the surface of the heat dissipation filler is modified with the silane compound, damage such as peeling, cracking, splitting, etc. of the matrix portion may easily occur due to external force such as elongation applied to the heat dissipation sheet. However, among the silane compounds, the amino silane compound can minimize or prevent such damage, and has the advantage of improving the heat dissipation characteristics and expressing the heat dissipation characteristics for a long time even in an environment to which an external force is applied. Furthermore, regarding a change in thickness of the matrix including a cured rubber-based resin even under extreme conditions, amino silane has an advantage in that it can improve this problem, compared to other types of silane compounds

As the amino silane compound, a known amino silane compound may be used, for example, one or more selected from the group consisting of 3-aminopropylmethyldiethoxysilane, 3-aminopropyldimethylethoxysilane, 3-aminopropyltriethoxysilane, 3-aminopropyltrimethoxysilane, 4-aminobutyltrimethoxysilane, 3-(meta-aminophenoxy)propyltrimethoxysilane, and normal-(2-aminoethyl)-3-aminopropylmethyldimethoxysilane may be used. Preferably 3-aminopropyltriethoxysilane, 3-aminopropyltrimethoxysilane and 3-aminopropylmethyldimethoxysilane may be used.

In addition, the amino silane compound may be provided in an amount of 1.0 to 4.0 parts by weight, more preferably 2.5 to 4.0 parts by weight based on 100 parts by weight of the heat dissipation filler, thereby improving heat dissipation characteristics. That is, the use of the amino silane compound is advantageous for achieving the object of the present invention, and at the same time, is advantageous for improving the adhesion of the matrix to be uniform. If the amino silane compound is contained in an amount of less than 1.0 part by weight, the achievement of the desired effect through the amino silane compound may be insignificant. In addition, if the amino silane compound is provided in excess of 4.0 parts by weight, a release film may not be easily removed when the release film is removed, and the heat dissipation filler may be adhered to the release film. In addition, there is a fear that the flexibility of the heat dissipation sheet may decrease.

Meanwhile, the amino silane compound is provided on the surface of the heat dissipation filler, and when the amino silane compound is included in the matrix formation, it may be difficult to improve the interfacial characteristics between the heat dissipation filler and the matrix.

Next, a matrix, which is a substrate in which the above-described heat dissipation filler is dispersed, will be described. The matrix is a carrier for accommodating the heat dissipation filler, and functions to maintain the shape of the heat dissipation sheet. The matrix may be formed through a matrix forming component, which is an organic compound used to prepare a conventional sheet. However, the matrix may be formed of a main resin containing a rubber-based resin such that the heat dissipation sheet includes the heat dissipation filler in an increased content, and phenomena such as cracking, shrinkage or pore occurrence in the implemented heat dissipation sheet is reduced or prevented. In addition, the rubber-based resin imparts flexibility to the heat dissipation sheet, may be advantageous in expressing excellent adhesion even on a stepped surface, and minimize or prevent pore occurrence, thereby preventing deterioration of heat dissipation characteristics due to pores.

With respect to the rubber-based resin, any known rubber-based resin may be selected without limitation in its type. For example, the rubber-based resin may include one or more selected from the group consisting of isoprene rubber (IR), butadiene rubber (BR), butyl rubber (IIR), styrene-butadiene rubber (SBR), ethylene propylene diene monomer (EPDM) rubber, acrylic rubber, nitrile-butadiene rubber (NBR), fluoro rubber, urethane rubber and silicone rubber. For example, the rubber-based resin may be styrene-butadiene rubber, and has advantages in terms of excellent solubility in solvents, low manufacturing cost, increased breath of selection of curing agents, and low density, compared to other types.

In addition, the weight average molecular weight of the rubber-based resin is preferably adjusted within an appropriate range. The rubber-based resin with a low molecular weight is advantageous for remarkably improving the content of the heat dissipation filler, but may be disadvantageous in terms of thermal conductivity. In addition, the rubber-based resign with a high molecular weight is advantageous for thermal conductivity, but may make it difficult to increase the content of the heat dissipation filler in the heat dissipation sheet. In addition, preferably, the rubber-based resin may have the density of 1 g/m³ or less, which has an advantage in that the content of the heat dissipation filler in the matrix can be increased. If the rubber-based resin having the density exceeding the range is used, it may be difficult to increase the content of the heat dissipation filler to be provided in the heat dissipation sheet, and accordingly, it may be difficult to achieve sufficient heat dissipation characteristics.

On the other hand, in addition to the above-mentioned rubber-based resin, other types of resin may be additionally contained. Even in this case, it may be better to use a resin having a low density in order to increase the content of the heat dissipation filler in the matrix, and for example, the density may be less than 1 g/m³. However, even when other types of resin are included as an auxiliary, the resin is preferably used in an amount of 10% by weight or less based on the total weight of the matrix. The other types of resins may be, for example, one or more selected from the group consisting of high-density polyethylene, polycarbonate, polyamide, polyimide, polyvinyl chloride, polypropylene, polystyrene, polyisobutylene, modified polypropylene ether (PPE), polyethyleneimide (PEI), polyetheretherketone (PEEK), acrylonitrile-butadiene-styrene (ABS), epoxy-based, acrylic-based, and polyurethane.

On the other hand, in implementing the heat dissipation sheet having a low dielectric characteristics as well as a heat dissipation characteristics, the rubber-based resin may have a dielectric constant of preferably 4.0 or less, more preferably 3.5 or less at 28 GHz, so that the desired dielectric constant characteristics may be easily achieved.

On the other hand, although the rubber-based resin has a different degree of elastic restoring force depending on the specific type, the resin has an elastic restoring force of a certain level or more, so it is advantageous to provide a high content of heat dissipation filler in the sheet, but it is not easy to implement the sheet with a thin thickness. That is, it is not easy to increase the density of the heat dissipation sheet, and the heat dissipation sheet undergoes a process of pressing the heat dissipation sheet to increase the density. However, it is not easy to increase the density of the implemented sheet including the rubber-based resin as it is restored to the thickness before compression by the elastic restoring force after a predetermined time has elapsed even after the sheet is compressed to a desired thickness. Accordingly, the matrix of the present invention includes a crosslinked rubber-based resin, through which the density after compression can be maintained even over time, and mechanical strength can be improved by increasing the bonding force between the components constituting the matrix. In addition, since the distance between the heat dissipation fillers is close in the thickness direction of the heat dissipation sheet or the contact between the heat dissipation fillers can be significantly increased, it may be more advantageous to improve the thermal conductivity in the vertical direction.

The crosslinking can be achieved through a crosslinking agent. In consideration of the type of rubber-based resin selected, a crosslinking agent that is known to be suitable for crosslinking may be used without limitation. For example, the crosslinking agent may be one or more selected from the group consisting of polyolefin-based, isocyanate-based, and peroxide-based. From the viewpoint of being advantageous in minimizing the increase in thickness that may occur under various conditions of use after crosslinking the rubber-based resin, particularly styrene-butadiene rubber, and in maintaining an initially set density, the crosslinking agent may preferably be one or more of an isocyanate-based and a peroxide-based type. On the other hand, in terms of mass production, the isocyanate-based crosslinking agent may be more advantageous in terms of storage stability of the sheet forming composition and the surface quality during sheet formation. In the case of the isocyanate-based crosslinking agent, a known crosslinking agent may be used, and for example, a block isocyanate-based crosslinking agent may be used.

In addition, the crosslinking agent may be contained in an amount of 1 to 10 parts by weight, more preferably 3 to 7 parts by weight, based on 100 parts by weight of the rubber-based resin. If the crosslinking agent exceeds 10 parts by weight, flexibility is reduced, and matrix hardness and brittle characteristics are increased, so that damage such as matrix breakage may easily occur. In addition, when the amount of the crosslinking agent is less than 1 part by weight, the sheet formability, shape stability, and heat resistance of the heat dissipation sheet may be deteriorated, and it may be difficult to implement the density of the heat dissipation sheet to a desired level.

In addition, the matrix may further include known components such as a flame retardant, an antifoaming agent, a leveling agent, and a UV stabilizer as other additives in addition to the above-described components.

According to the increase in compatibility between the surface-modified heat dissipation filler and the matrix having the crosslinked rubber-based resin, the heat dissipation filler may be provided in 90% by weight or more, more preferably 90 to 96% by weight of the total weight of the matrix and heat dissipation filler. Thus, even in a state in which the heat dissipation filler is provided with a high content, breakages or cracks may not occur. If the heat dissipation filler exceeds 96% by weight, it may be difficult to form a sheet. In addition, the heat dissipation sheet may have the density of 1.7 g/m³ or more, more preferably 1.8 g/m³ or more, through which the heat dissipation filler may be dispersed at a high filling rate, and the sheet can be implemented in a very thin thickness, thereby having advantages in achieving excellent heat dissipation characteristics.

In addition, the heat dissipation sheet may have a thickness of 5 to 200 μm, and may be 20 to 100 μm, but is not limited thereto, and may be appropriately changed in consideration of an application place, heat dissipation performance, and the like.

The above-described heat dissipation sheet may be manufactured by a manufacturing method described later, but is not limited thereto.

The heat dissipation sheet according to an embodiment of the present invention may be manufactured by the method including the steps of (1) preparing a heat dissipation filler of which surface is modified with a silane compound, (2) preparing a preliminary sheet by mixing the heat dissipation filler with a rubber-based resin, and (3) crosslinking the rubber-based resin while pressing the prepared preliminary sheet.

First, as the step (1), the step of preparing the heat dissipation filler of which surface is modified with a silane compound is performed. The surface modification may be performed by appropriately employing a known method in consideration of the specific type of the silane compound. For example, after wetting the heat dissipation filler using an organic solvent such as ethanol, it is mixed with a silane compound and stirred at 40 to 80° C. for 3 hours or more, and then washed and dried to obtain the heat dissipation filler with the modified surface.

Next, as the step (2) of the present invention, the step of preparing a preliminary sheet by mixing the surface-modified heat dissipation filler with a rubber-based resin and a crosslinking agent is performed.

The preliminary sheet refers to one in which a sheet forming composition including the rubber-based resin, the crosslinking agent, and the heat dissipation filler is implemented in a sheet shape through a conventional sheet forming method. The sheet forming composition may further include a known solvent suitable for dissolving the rubber-based resin, and the preliminary sheet may be in a state in which the solvent included in the sheet composition is dried. Alternatively, the preliminary sheet may be in a state in which a portion of the matrix forming component is crosslinked through the crosslinking agent.

For example, the solvent may be a non-polar solvent such as toluene, xylene, methyl ethyl ketone, and the like. For example, the content of the solvent may be 100 to 1,000 parts by weight based on 100 parts by weight of the main resin, and the content may be adjusted in consideration of an appropriate viscosity or the type of the main resin according to a sheet forming method.

The sheet composition may be subject to a stirring process using a 3-Roll-Mill and/or PL mixer to uniformly disperse the heat dissipation filler and obtain an appropriate viscosity. The stirring process may use a high-power disperser such as 3-Roll-Mill to improve the dispersibility of the heat dissipation filler, and to improve the thermal conductivity, density and flexibility of the heat dissipation sheet.

In addition, a defoaming process for removing bubbles generated in the stirring process may be performed together with the stirring process or after the stirring process.

Thereafter, the homogeneously prepared sheet composition may have a viscosity of 1500 to 3500 cps as an example, and 2000 to 3000 cps as another example. In addition, the sheet forming composition may be prepared as a preliminary sheet by a conventional method, for example, may be processed on a substrate to form a sheet shape. A method of treating the sheet composition on the substrate may employ a known coating method. For example, knife coating using a comma coater may be used, but is not limited thereto.

In addition, the sheet composition processed into a sheet phase on the substrate may be dried at 70 to 130° C. In another example, the sheet composition may be dried at an initial temperature of 70 to 85° C., and then the drying temperature may be increased up to a final temperature of 110 to 130° C. for completing the drying. In addition, since the drying time may vary depending on the drying temperature, the present invention is not particularly limited thereto. On the other hand, the thickness of the dried preliminary sheet may be 80 to 150 μm, but is not limited thereto.

Next, as the step (3), the step of crosslinking the rubber-based resin while pressing the prepared preliminary sheet may be performed.

The crosslinking may be performed by an appropriate method depending on the type of the rubber-based resin and the type of the crosslinking agent. For example, it may be a thermal crosslinking reaction by heat treatment or a photo crosslinking reaction by light irdissipation. For example, when the crosslinking reaction is induced by heat treatment, it may be carried out by applying heat of 120 to 170° C. In this case, the application of pressure can be done with crosslinking to achieve a desired level of thickness and increase the density. In this case, the pressure may be applied to the preliminary sheet through a plate press method or a calendar method.

The step (3) according to an embodiment of the present invention may include the steps of crosslinking while applying heat and pressure with respect to at least one preliminary sheet, and cooling the crosslinked preliminary sheet.

The crosslinking step can induce a thermal crosslinking reaction while applying pressure. Through this, in addition to realizing the desired thickness, the density of the heat dissipation sheet can be increased, and the content of the heat dissipation filler per unit volume can be further increased, and at the same time, the distance between the heat dissipation fillers can be shortened depending on the pressure, so there is an advantage that heat dissipation characteristics can be further improved. In addition, when the heat dissipation filler has a plate shape, the orientation in the horizontal direction within the heat dissipation sheet is improved, and the vertical distance between the heat dissipation fillers is shortened, so that both the horizontal and vertical heat dissipation characteristics can be improved. At this time, the applied pressure may be 2.5 to 5 kgf/mm², so that it may be advantageous in achieving the desired effect of the present invention.

In addition, the heat applied in the crosslinking step may be 100 to 180° C., preferably 110 to 170° C., more preferably 150 to 180° C., the execution time may be 10 to 60 minutes, more preferably 15 to 55 minutes.

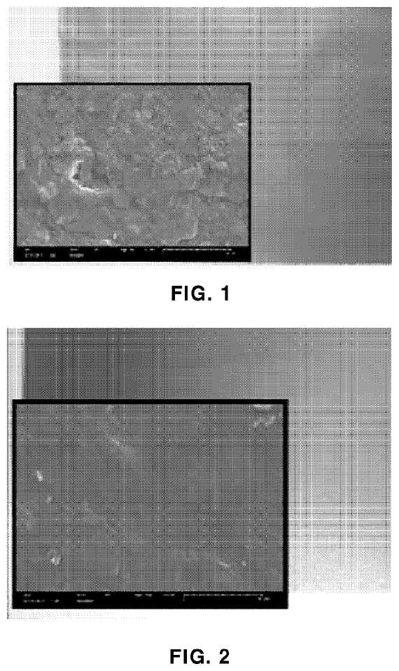

In addition, the cooling step is to avoid the problems of density reduction and non-uniform thickness due to matrix expansion occurring when left at room temperature after crosslinking through heat, and has the advantage of realizing the heat dissipation sheet having a higher density and uniform thickness. In addition, it is possible to realize the heat dissipation sheet having a better surface quality through the cooling step. As shown in FIGS. 1 and 2, it can be confirmed that the surface quality of the heat dissipation sheet of FIG. 2 in which the cooling step is performed is superior to the surface of the heat dissipation sheet of FIG. 1 in which the cooling step is not performed after crosslinking through heat.

The cooling step may be terminated when the manufactured heat dissipation sheet is cooled to a temperature of 60° C. or less, preferably 18 to 60° C., and more preferably 18 to 50° C. In addition, the cooling step may be performed for 10 to 60 minutes, preferably 15 to 55 minutes. In addition, the cooling rate may be, for example, 5 to 30° C./min. If the cooling temperature exceeds 60° C., there is a risk of thickness fluctuation, and in the cooling process, the heat dissipation sheet may be attached to a cooling device, for example, a surface of a press and not easily detach from it, and this significantly increases the deterioration of the surface quality of the heat dissipation sheet and there is a risk of lowering productivity.

In addition, the cooling step may also be performed while applying a pressure, so that there is an advantage that can minimize the thickness variation of the heat dissipation sheet. At this time, the applied pressure may be, for example, 2.5 to 5 kgf/mm².

On the other hand, the steps of crosslinking and cooling may be performed while applying pressure through a first press and a second press having different temperatures. In this case, productivity can be further improved compared to when the temperature condition is changed using one press, and the time between the crosslinking step and the cooling step can be minimized or easily adjusted to a desired level, so there is advantage of improving the quality of the heat dissipation sheet. The temperature and pressing time of the first press may be the temperature and execution time of the above-described crosslinking step, and the temperature and pressing time of the second press may be the temperature and execution time of the above-described cooling step.

On the other hand, the crosslinking step may be performed while applying pressure in a state in which 2 to 5 preliminary sheets are stacked. Rather than crosslinking while applying pressure to one preliminary sheet, crosslinking while applying pressure to the stacked multiple preliminary sheets is the preferred method for achieving the desired level of the thickness and density of the heat dissipation sheet and improving productivity. If more than 5 preliminary sheets are stacked, the preliminary sheets may be pushed during the pressurization process, so uniform pressure may not be performed, and there is a risk of thickness variation depending on the location of the heat dissipation sheet.

On the other hand, if the thickness of one preliminary sheet is very thin (for example, 40 μm or less), it may not be easy to stack the preliminary sheets in the process. Therefore, in this case, it is preferable to perform the step (3) for one sheet, without stacking multiple sheets.

The sheet thickness of the heat dissipation sheet manufactured by performing step (3) may be, for example, 100 μm or less, and in another example, the sheet thickness may be 30 to 60 μm.

On the other hand, the preliminary sheet manufactured through the step (2) and the heat dissipation sheet manufactured through the step (3) may have the thickness reduction rate of 20% or more, preferably 25%, more preferably 40% or more, calculated according to Equation 1 below. Accordingly, the high content and high density design of the heat dissipation filler in the heat dissipation sheet is possible, which may be more advantageous in improving heat dissipation characteristics.

$$thickness reduction rate ( \% ) = \frac{\begin{matrix}thickness of preliminary sheet ( μm ) - \\ thickness of heat dissipation sheet ( μm )\end{matrix}}{thickness of preliminary sheet ( μm )} \times 100 \qquad [ Equation 1 ]$$

In addition, although in the heat dissipation sheet manufactured through the step (3), a matrix is implemented using a rubber-based resin, a thickness change rate calculated by Equation 2 below after left at 40° C. for 50 hours may be 10% or less, preferably 5% or less, more preferably 2% or less, even more preferably 1% or less, even more preferably 0.5% or less. Through this, there is an advantage in minimizing the deterioration of the heat dissipation characteristics that occur as the thickness increases or the quality deterioration due to a shape deformation such as thickness fluctuates or non-uniform thickness after the implementation of the heat dissipation sheet.

$$\begin{matrix}thickness \\ change rate ( \% )\end{matrix} = \frac{\begin{matrix}thickness of dissipation sheet after left ( μm ) - \\ thickness of heat dissipation sheet before left ( μm )\end{matrix}}{thickness of heat dissipation sheet before left ( μm )} \qquad [ Equation 2 ]$$

On the other hand, the heat dissipation sheet according to an embodiment of the present invention implemented through the above-described manufacturing method may have a structure in which the heat dissipation filler is dispersed in the matrix formed by crosslinking the matrix forming component.

In addition, the heat dissipation sheet may have a density of 1.7 g/m³ or more, preferably 1.8 g/m³ in a state in which the heat dissipation filler is provided in 85% by weight or more, more preferably 90% by weight or more, and even more preferably 96% by weight or less of the total weight of the heat dissipation sheet. Therefore, the heat dissipation sheet may be implemented with a very thin thickness while the filling rate of the heat dissipation filler dispersed therein is high, so it can be advantageous to achieve excellent heat dissipation characteristics. On the other hand, when the heat dissipation filler is provided in excess of 96% by weight in the heat dissipation sheet, it is difficult to form the sheet, and there is a risk that it may be easily broken.

In addition, the heat dissipation sheet according to an embodiment of the present invention may be implemented to have low dielectric characteristics and heat dissipation characteristics. In this case, the heat dissipation sheet may have a dielectric constant of 10 or less, more preferably 4 or less at a frequency of 28 GHz. The heat dissipation sheet expressing such a low dielectric characteristic has the advantage of preventing signal disturbance or signal attenuation transmitted and received by adjacent parts. More specifically, at a predetermined frequency, for example, 1 GHz, 5 GHz, 10 GHz, 15 GHz, 20 GHz, 25 GHz, 28 GHz, 30 GHz, or 35 GHz, the heat dissipation sheet may be implemented to have a low dielectric characteristic with a dielectric constant of 4 or less. In addition, the heat dissipation sheet has a thermal conductivity of 25 W/mk or more, preferably 40 W/mk or more, more preferably 50 W/mk or more, and even more preferably 55 W/mk or more, even though the heat dissipation sheet exhibits the low dielectric characteristics as described above. Therefore, excellent heat dissipation characteristics can be expressed.

### EXAMPLES

The present invention will be described in more detail through the following examples, but the following examples are not intended to limit the scope of the present invention, which should be construed to aid understanding of the present invention.

### Example 1

Based on 100 parts by weight of SBR (200° C. 5 g/min, weight average molecular weight of 900,000), 3 parts by weight of bis(tert-butylphenoxy-2-isopropyl)benzene, which is a peroxide-based crosslinking agent, 1200 parts by weight of plate-shaped boron nitride having a surface modified with 3-aminopropyltriethoxysilane that is amino silane compound and having an average particle diameter of 32 μm, as a heat dissipation filler, and ethanol as a solvent were mixed and stirred to prepare a sheet forming composition having a viscosity of about 2500 cps. The prepared sheet forming composition was treated on a substrate to a predetermined thickness using a comma coater, and then dried at 100° C. for 5 minutes to prepare a preliminary sheet having a thickness of about 100 μm. After attaching a release film on the preliminary sheet, a pressure of 3.1 kgf/mm² was applied using a first press of a temperature of 160° C. to induce a thermal crosslinking reaction for 40 minutes. Thereafter, a cooling process was performed for 40 minutes in a state of applying the pressure of 3.1 kgf/mm² using a second press of a temperature of 50° C. to prepare a heat dissipation sheet having a final thickness of 60 μm and a heat dissipation filler content of 90% by weight. In this case, boron nitride whose surface was modified with an amino silane compound was prepared by soaking the boron nitride in ethanol, mixing with 3-aminopropyltriethoxysilane, stirring at 60° C. for 4 hours, washing and drying. In the finally obtained boron nitride of which surface is modified with the amino silane compound, 2.5 parts by weight of the amino silane compound was provided with respect to 100 parts by weight of the boron nitride.

### Comparative Example 1

The same heat dissipation filler as in Example 1 was used, but 3 parts by weight of DICY as a curing agent and 200 parts by weight of methyl ethyl ketone as a solvent were mixed based on 100 parts by weight of the bisphenol A epoxy component (Kukdo, YG-011) as a matrix forming component, to prepare a sheet forming composition, and the prepared sheet forming composition was treated on a substrate to a predetermined thickness using a comma coater, cured at 150° C. for 30 minutes, and then cooled in the same manner as in Example 1 to prepare the heat dissipation sheet having the final thickness of 60 μm, and the content of the heat dissipation filler of about 90% by weight.

### Comparative Example 2

The same heat dissipation filler as in Example 1 was used, but it was carried out in the same manner as in Example 1, except that the matrix forming component was changed to thermoplastic polyurethane (TPU). The prepared heat dissipation sheet had the final thickness of 60 μm, and the content of the heat dissipation filler of about 90% by weight.

### Experimental Example 1

100 each of heat dissipation sheets according to Example 1 and Comparative Examples 1 and 2 were prepared in the same size. Then, among 100 specimens, the number of specimens with cracks or breakage and the number of specimens with pores on the surface or shrinkage were counted, and the results were shown as a percentage in Table 1 below.

TABLE 1

| | | Comparative | Comparative |
|---|---|---|---|
| | Example 1 | Example 1 | Example 2 |
| Matrix forming | Rubber-based | Epoxy | Polyurethane |
| component | component (SBR) | component | component |
| Percentage (%) of | 0 | 80 | 0 |
| cracked/broken sheets | | | |
| Percentage (%) of | 1 | 0 | 53 |
| shrunk/porous sheets | | | |

As seen in Table 1, it was confirmed that the heat dissipation sheet of Example 1 using the rubber-based component as the matrix forming component did not generate cracks or breakages, did not change shape such as shrinkage, and had excellent surface quality.

### Example 2

Based on 100 parts by weight of SBR (200° C. 5 g/min, weight average molecular weight of 900,000), 3 parts by weight of bis(tert-butylphenoxy-2-isopropyl)benzene, which is a peroxide-based crosslinking agent, and 2136 parts by weight of plate-shaped boron nitride having a surface modified with amino silane compound and having an average particle diameter of 32 μm, which was used in Example, as a heat dissipation filler, and toluene as a solvent were mixed and stirred to prepare a sheet forming composition having a viscosity of about 2500 cps. The prepared sheet forming composition was treated on a substrate to a predetermined thickness using a comma coater, and then dried at 100° C. for 5 minutes to prepare a preliminary sheet. After stacking three preliminary sheets, a release film was attached on the uppermost preliminary sheet, and a pressure of 3.1 kgf/mm² was applied using a first press of a temperature of 160° C. to induce a thermal crosslinking reaction for 40 minutes. Thereafter, a cooling process was performed for 40 minutes under a pressure of 3.1 kgf/mm² using a second press of a temperature of 50° C. to prepare a heat dissipation sheet as shown in Table 2 below.

### Example 3

It was prepared in the same manner as in Example 2, except that the type of crosslinking agent was changed to hexamethylene diisocyanate to prepare a preliminary sheet, and a heat dissipation sheet as shown in Table 2 was prepared through crosslinking and cooling processes.

### Comparative Example 3

It was prepared in the same manner as in Example 2, but without adding a crosslinking agent, a heat dissipation sheet as shown in Table 2 was prepared.

### Experimental Example 2

The following physical properties were evaluated for the heat dissipation sheets according to Examples 2 to 3 and Comparative Example 3, and the results are shown in Table 2.

Specifically, after measuring dimensions such as thickness and weight immediately after manufacturing the heat dissipation sheet, the thickness reduction rate was calculated according to Equation 1 below. In addition, the thickness change rate was calculated according to Equation 2 below after the manufactured heat dissipation sheet was left at 40° C. for 50 hours.

$$thickness reduction rate ( \% ) = \frac{\begin{matrix}thickness of preliminary sheet ( μm ) - \\ thickness of heat dissipation sheet ( μm )\end{matrix}}{thickness of preliminary sheet ( μm )} \times 100 \qquad [ Equation 1 ]$$

$$\begin{matrix}thickness \\ change rate ( \% )\end{matrix} = \frac{\begin{matrix}thickness of dissipation sheet after left ( μm ) - \\ thickness of heat dissipation sheet before left ( μm )\end{matrix}}{thickness of heat dissipation sheet before left ( μm )} \qquad [ Equation 2 ]$$

TABLE 2

| | | | Comparative |
|---|---|---|---|
| | Example 2 | Example 3 | Example 3 |
| Matrix forming component | SBR | SBR | SBR |
| Type of crosslinking agent | Peroxide- | Isocyanate- | Not used |
| | based | based | |
| Thickness of preliminary | 140 | 140 | 140 |
| sheet (μm) | | | |
| Thickness of heat dissipa- | 82.0 | 82.0 | 101.0 |
| tion sheet immediately | | | |
| after manufactured (μm) | | | |
| Thickness reduction rate | 41.4 | 41.4 | 27.9 |
| (%) | | | |
| Density (g/m³) | 1.81 | 1.81 | 1.71 |
| Thickness of heat dissipa- | 82.2 | 88.2 | 138 |
| tion sheet after left for | | | |
| 50 hours (μm) | | | |
| Thickness change rate (%) | 0.3 | 7.6 | 36.6 |

As seen in Table 2, in Example 2 in which a peroxide type crosslinking agent was used and Example 3 in which an isocyanate type crosslinking agent was used, the thickness change rate after preparation was 10% or less, which was superior to that in Comparative Example 3.

### Examples 4 to 6

It was prepared in the same manner as in Example 2, but the cooling temperature was changed as shown in Table 3 below to prepare a heat dissipation sheet as shown in Table 3 below.

### Experimental Example 3

For the heat dissipation sheets of Example 2 and Examples 4 to 6, the thickness change rate was calculated in the same manner as in Experimental Example 2. In addition, among a total of 1000 manufactured heat dissipation sheets for each Example, the number of heat dissipation sheets attached to the second press was counted and shown in Table 3 below.

TABLE 3

| | Example 2 | Example 4 | Example 5 | Example 6 |
|---|---|---|---|---|
| Matrix forming | SBR | SBR | SBR | SBR |
| components | | | | |
| Type of crosslinking | Peroxide- | Peroxide- | Peroxide- | Peroxide- |
| agent | based | based | based | based |
| Cooling temperature | 50 | 60 | 65 | 70 |
| (° C.) | | | | |
| Thickness of pre- | 140 | 140 | 140 | 140 |
| liminary sheet (μm) | | | | |
| Thickness of heat | 82.0 | 82.0 | 82.0 | 82.0 |
| dissipation sheet | | | | |
| immediately after | | | | |
| manufactured (μm) | | | | |
| Thickness reduction | 41.4 | 41.4 | 41.4 | 41.4 |
| rate (%) | | | | |
| Thickness of heat | 82.2 | 82.74 | 83.80 | 86.76 |
| dissipation sheet | | | | |
| after being left for | | | | |
| 50 hours (μm) | | | | |
| Thickness change rate | 0.3 | 0.9 | 2.2 | 5.8 |
| (%) | | | | |
| Number of heat | 0 | 3 | 26 | 100 |
| dissipation sheets | | | | |
| attached to a second | | | | |
| press | | | | |

As seen in Table 3, it was confirmed that when the cooling temperature exceeded 60° C., the number of heat dissipation sheets adhered to the second press increased, and the thickness change rate also increased.

### Example 7

A heat dissipation sheet was manufactured in the same manner as in Example 2, except for performing a cooling process.

### Experimental Example 3

For the heat dissipation sheets according to Examples 2 and 7, surface SEM photographs were taken, and the results were shown in FIGS. 1 (Example 7) and 2 (Example 2).

As seen in FIGS. 1 and 2, it was confirmed that FIG. 1 which is a photograph of the heat dissipation sheet of Example 7 that has not undergone the cooling process showed a rough surface, whereas the surface quality of the heat dissipation sheet of Example 2 that has been subjected to the cooling process showed excellent.

### Examples 7 to 18

The heat dissipation sheet as shown in Tables 4 and 5 was manufactured in the same manner as in Example 2, except that the particle size of the heat dissipation filler and the content of the heat dissipation filler were changed as shown in Tables 4 and 5 below.

### Experimental Example 4

The following physical properties were evaluated for the heat dissipation sheets according to Example 2 and Examples 7 to 18, and were shown in Tables 4 and 5 below.

1. Evaluation of Heat Dissipation Characteristics

Thermal conductivity was calculated using the thermal diffusivity measured using LFA, specific heat measured using DSC, and the density of the heat dissipation sheet.

In addition, after placing the LED at a predetermined interval on the circumference of a circle with a diameter of 25 mm, a thermometer was placed in the center of the circle, and a measuring equipment was manufactured so that a predetermined voltage could be applied to the LED. The measuring equipment was placed in an acrylic chamber of 32 cm×30 cm×30 cm in width, length, and height, respectively, and the temperature inside the acrylic chamber was adjusted to be 25±0.2° C. After placing a heat dissipation sheet on the LED of the measuring equipment, a predetermined input power was applied to the LED, and after a predetermined time had elapsed, a thermal image was taken from the upper portion of the heat dissipation sheet and the temperature of the thermometer in the measuring equipment was measured. Afterwards, the average temperature of the portion of the heat dissipation sheet corresponding to the LED was calculated to show the average temperature through the results of thermal imaging, and the temperature calculated through the thermometer in the measuring equipment was shown as the T.C value, respectively.

In addition, as a standard for evaluating heat dissipation performance, the same input power was applied to the LED of the measuring equipment in the absence of the heat dissipation sheet, and after the same time had elapsed, thermal imaging was taken from the upper portion of the LED and the temperature of the thermometer in the measuring equipment was measured, and the result was defined as a default value, and the average temperature taken in the thermal image without the heat dissipation sheet was 53.8° C., and the T.C. was 66.3° C.

On the other hand, in the case of Example 8, the measurement was impossible because the specimen was severely cracked during the measurement process.

2. Surface Quality

In order to evaluate the amount of heat dissipation fillers come off from the surface of the heat dissipation sheet, an adhesive sheet of the same size as the manufactured heat dissipation sheet was attached to one surface of the heat dissipation sheet and then removed. The peeled adhesive sheet was divided into 10 horizontally and vertically to partition them into a total of 100 cells, and the number of cells on which the heat dissipation filler was adhered was counted.

3. Flexibility Assessment

For a total of 1000 heat dissipation sheets for each example, it was observed whether cracks or breakage occurred when bent with a curvature of 20 mm, and the number of sheets in which cracks or breakage occurred was counted.

TABLE 4

| | | Example 2 | Example 7 | Example 8 | Example 9 | Example 10 |
|---|---|---|---|---|---|---|
| Thickness of heat | | 82 | 82 | 82 | 82 | 82 |
| dissipation sheet(μm) | | | | | | |
| heat | Total content | 93 | 96 | 97 | 93 | 93 |
| dissipation | (wt %) | | | | | |
| filler | Particle | 32 | 32 | 32 | 40 | 45 |
| | diameter(μm) | | | | | |

| | | | | | |
|---|---|---|---|---|---|
| Thermal | 53.6 | 60.0 | Not | 63.2 | 67.9 |
| conductivity(W/mK) | | | measurable | | |
| Flexibility | 20 | 45 | — | 28 | 62 |
| Surface quality | 16 | 48 | — | 24 | 55 |

TABLE 5

| | | Example 11 | Example 12 | Example 13 | Example 14 | Example 15 | Example 16 | Example 17 | Example 18 |
|---|---|---|---|---|---|---|---|---|---|
| Thickness of heat | | 82 | 82 | 82 | 82 | 82 | 82 | 82 | 82 |
| dissipation | | | | | | | | | |
| sheet(μm) | | | | | | | | | |
| heat | Total | 95 | 95 | 95 | 95 | 95 | 95 | 95 | 95 |
| dissipation | content(wt %) | | | | | | | | |
| filler | A(μm) | 30 | 25 | 30 | 40 | 30 | 50 | 30 | 30 |
| | B(μm) | 1 | 7 | 5 | 3 | 10 | 3 | 5 | 5 |
| | A:B wt % | 8.5:1 | 8.5:1 | 8.5:1 | 8.5:1 | 8.5:1 | 8.5:1 | 6:1 | 10:1 |

| | | | | | | | | |
|---|---|---|---|---|---|---|---|---|
| Thermal | 52.4 | 52.8 | 55.2 | 60.3 | 58.4 | 78.5 | 46.7 | 55.9 |
| conductiviy | | | | | | | | |
| (W/mK) | | | | | | | | |
| Flexibility | 14 | 0 | 0 | 10 | 17 | 46 | 7 | 16 |
| Surface quality | 30 | 0 | 0 | 5 | 10 | 44 | 18 | 7 |

As seen in Table 4, it was confirmed that when the content of the heat dissipation filler was high as in Example 8, the flexibility of the heat dissipation sheet was lowered. In addition, in the case of Example 10 having a rather large average particle diameter, the surface quality was not good, and thus, it was confirmed that the heat dissipation characteristic was lowered compared to that of Example 4.

In addition, as seen in Table 5, in the case of Examples 12 to 14, compared to Examples 11 and 15 to 18, it was confirmed that the heat dissipation performance was excellent, and flexibility and surface quality were good.

### Examples 19 to 20

The heat dissipation sheet as shown in Table 6 was prepared in the same manner as in Example 13, except that the type of the silane compound was changed to vinyltrimethoxysilane, which is a vinyl silane compound, or 3-glycidoxypropyltrimethoxysilane, which is an epoxy silane compound, respectively.

### Examples 21 to 24

A heat dissipation sheet as shown in Table 6 below was prepared in the same manner as in Example 13, except that the content of the silane compound was changed.

### Experimental Example 5

After peeling off the release film from the heat dissipation sheet according to Example 3, Examples 19 to 24, a protective film with a thickness of 5 μm in which an adhesive layer of 3 μm was formed on one side of a PET film having a thickness of 2 μm was attached to the matrix surface. Then, after partially separating the interface on the side between the protective film and the matrix of the heat dissipation sheet, the separated protective film was peeled off using a tensile tester ASTM D903 condition until the protective film broke. Then, by observing the peeled matrix of the heat dissipation sheet, it was confirmed whether the matrix was separated by some thickness in the thickness direction, by performing an experiment on a total of 20 specimens for each Example and Comparative Example. For 20 specimens, the case where the matrix was not peeled off and the protective film was neatly separated was indicated by x, and the case where the matrix was partially separated in the thickness direction was indicated by ∘, and the number was indicated together. The results were shown in Table 6 below.

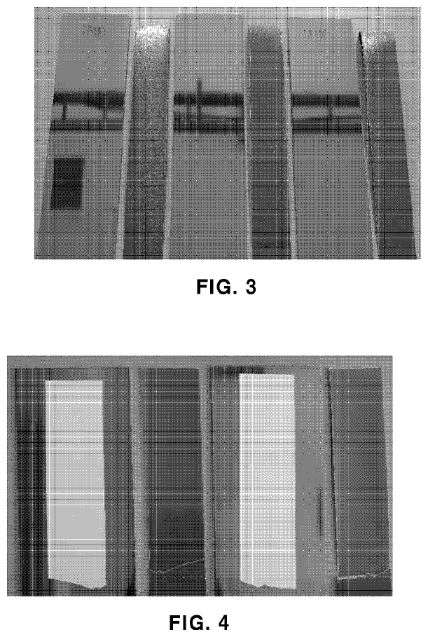

In addition, after the evaluation of Example 13 and Examples 19 and 20, pictures were taken and shown in FIGS. 3 to 5, respectively.

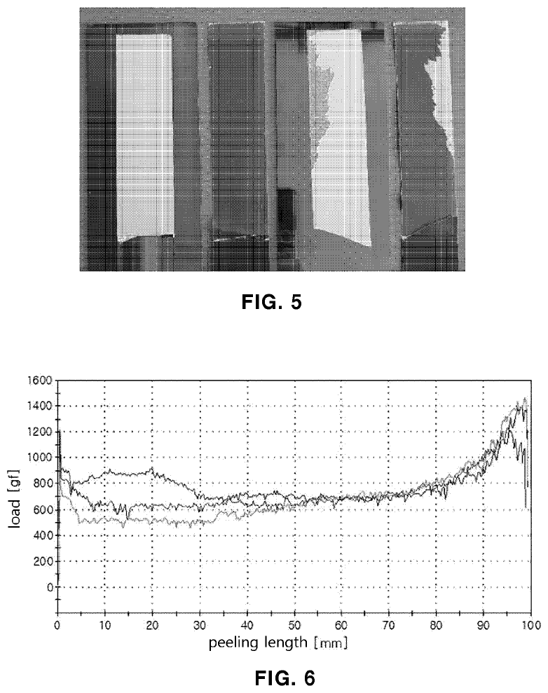

It was confirmed that in the case of Example 13 of FIG. 3, tearing did not occur in the matrix, but in the case of Examples 19 and 20 of FIGS. 4 and 5, the matrix was torn.

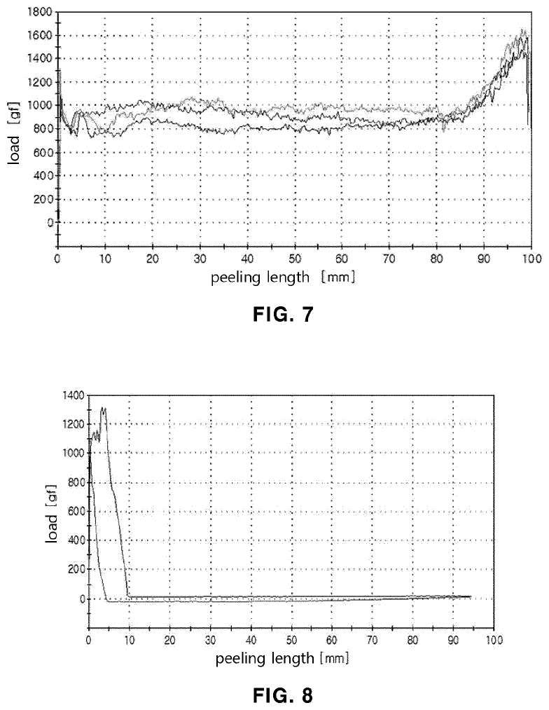

In addition, the graphs of adhesive force according to the peeling length of the protective film for Example 13, Example 23, Example 19, and Example 20 were shown in FIGS. 6 to 9, respectively.

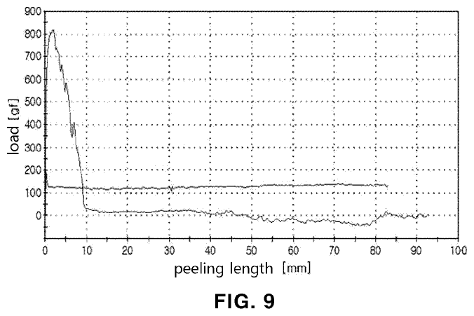

As seen in FIGS. 8 and 9, in the case of Examples 19 and 20, the adhesive force was remarkably reduced to 0 level shortly after the start of the evaluation, which confirmed that the matrix was peeled off at any point in the thickness direction.

### Experimental Example 6

After removing the release film after manufacturing the heat dissipation sheet according to Example 13 and Examples 18 to 24, the presence or absence of the heat dissipation filler remaining on the release film was visually checked. The case where the heat dissipation filler remained was indicated by ∘ The case where the heat dissipation filler did not remain was indicated by x.

TABLE 6

| | Example 3 | Example 19 | Example 20 | Example 21 | Example 22 | Example 23 | Example 24 |
|---|---|---|---|---|---|---|---|
| Silane | Amino | Vinyl | Epoxy | Amino | Amino | Amino | Amino |
| compound(Type/ | silane/2.5 | silane/2.5 | silane/2.5 | silane/0.5 | silane/1.0 | silane/4.0 | silane/5.0 |
| content(wt %) | | | | | | | |
| Location of | Surface | Surface | Surface | Surface | Surface | Surface | Surface |
| silane compound | of heat | of heat | of heat | of heat | of heat | of heat | of heat |
| | dissipation | dissipation | dissipation | dissipation | dissipation | dissipation | dissipation |
| | filler | filler | filler | filler | filler | filler | filler |
| Thermal | 55.2 | 55.0 | 53.5 | 54.8 | 55.0 | 55.0 | 45.0 |
| conductivity | | | | | | | |
| (W/mK) | | | | | | | |
| Whether/number | x | ∘/20 | ∘/20 | ∘/18 | ∘/5 | x | x |
| of matrix | | | | | | | |
| separation | | | | | | | |
| Whether heat | x | x | x | x | x | x | ∘ |
| dissipation filler | | | | | | | |
| is adhered to | | | | | | | |
| release film | | | | | | | |

As seen in FIGS. 3 to 6, FIGS. 8 and 9 and Table 6, it was confirmed that in the heat dissipation sheets according to Examples 19 and 20 where the silane compounds having a vinyl group and an epoxy group were used, the matrix itself was separated by a certain thickness. As a result, it was expected that the interfacial bonding between the heat dissipation filler of boron nitride and the matrix was not good, so that the interface was lifted, and the lift portion was torn out by the applied external force. However, in the case of Example 13 using the silane compound having an amino group, it was confirmed that the interfacial bond between the heat dissipation filler of boron nitride and the matrix was good, so that the matrix separation did not occur based on these interfaces.

In addition, in the case of Example 24 where the content of the amino silane compound was high, it was confirmed that the matrix component was adhered to the release film, and the heat dissipation effect was also reduced.

Although one embodiment of the present invention has been described above, the spirit of the present invention is not limited to the embodiments presented herein, and those skilled in the art who understand the spirit of the present invention may easily suggest other embodiments by providing, changing, deleting, adding components within the scope of the same spirit, but this will also fall within the scope of the present invention.

1. A heat dissipation sheet comprising:
a matrix including a crosslinked rubber-based resin; and
a heat dissipation filler which is dispersed in the matrix and of which surface is modified with a silane compound.

2. The heat dissipation sheet according to claim 1, wherein the heat dissipation filler is provided in 90% by weight or more based on a total weight of the matrix and the heat dissipation filler.

3. The heat dissipation sheet according to claim 1, wherein the heat dissipation filler includes the heat dissipation filler having a resistance of 1×10¹⁴Ω or more.

4. The heat dissipation sheet according to claim 1, wherein the heat dissipation filler includes the heat dissipation filler having a dielectric constant of 10 or less at a frequency of 28 GHz.

5. The heat dissipation sheet according to claim 1, wherein the heat dissipation filler has an average particle diameter of 20 to 40 μm.

6. The heat dissipation sheet according to claim 1, wherein the rubber-based resin includes one or more selected from the group consisting of isoprene rubber (IR), butadiene rubber (BR), styrene-butadiene rubber (SBR), ethylene propylene diene monomer (EPDM) rubber, acrylic rubber, nitrile-butadiene rubber (NBR) and silicone rubber.

7. The heat dissipation sheet according to claim 1, wherein the rubber-based resin is crosslinked through a crosslinking agent including an isocyanate-based compound.

8. The heat dissipation sheet according to claim 1, wherein the silane compound includes amino silane compound.

9. The heat dissipation sheet according to claim 8, wherein the amino silane compound includes one or more selected from the group consisting of 3-aminopropyltriethoxysilane, 3-aminopropyltrimethoxysilane and 3-aminopropylmethyldimethoxysilane.

10. The heat dissipation sheet according to claim 1, wherein the matrix includes a crosslinked product in which styrene-butadiene rubber (SBR) is crosslinked with a crosslinking agent of an isocyanate-based compound, and the silane compound is an amino silane compound.

11. The heat dissipation sheet according to claim 8, wherein the amino silane compound is included in an amount of 1.0 to 4.0 parts by weight based on 100 parts by weight of the heat dissipation filler.

12. The heat dissipation sheet according to claim 1, wherein the heat dissipation filler has a plate shape, and includes a first heat dissipation filler having a particle diameter of 3 to 7 μm and a second heat dissipation filler having a particle diameter of 25 to 40 μm in a weight ratio of 1:7.5 to 9.5.

13. The heat dissipation sheet according to claim 1, wherein the heat dissipation sheet has a density of 1.8 g/m³ or more.

14. A method for manufacturing a heat dissipation sheet comprising the steps of:
(1) preparing a heat dissipation filler of which surface is modified with a silane compound;
(2) preparing a preliminary sheet by mixing the heat dissipation filler with a rubber-based resin and a crosslinking agent; and
(3) crosslinking the rubber-based resin while pressing the prepared preliminary sheet.

15. The method for manufacturing a heat dissipation sheet according to claim 14, wherein the step (3) is performed by a plate press method or a calendar method.

16. The method for manufacturing a heat dissipation sheet according to claim 14, wherein the step (3) includes the steps of:
crosslinking the preliminary sheet while applying heat and pressure at a temperature of 100 to 180° C.; and
cooling the crosslinked preliminary sheet to a temperature of 18 to 60° C. while applying pressure.

17. An electronic device comprising the heat dissipation sheet according to claim 1.
